(19) United States
(12) Patent Application Publication
(10) Pub. No.: US 2009/0283829 A1
(43) Pub. Date: Nov. 19, 2009

(54) FINFET WITH A V-SHAPED CHANNEL

(75) Inventors: Thomas W. Dyer, Pleasant Valley, NY (US); Haining S. Yang, Wappingers Falls, NY (US)

Correspondence Address: FREDERICK W. GIBB, III;Gibb Intellectual Property Law Firm, LLC, 2568-A RIVA ROAD, SUITE 304, ANNAPOLIS, MD, 21401, US

(73) Assignee: INTERNATIONAL BUSINESS MACHINES CORPORATION, ARMONK, NY (US)

(21) Appl. No.: 12/119,515

(22) Filed: May 13, 2008

(51) Int. Cl. H01L 21/8238; H01L 27/092

(52) U.S. Cl. 257/351; 438/199; 257/E27.112; 257/E21.632; 257/E27.062

(57) ABSTRACT

A fin-type field effect transistor (finFET) structure comprises a substrate having a planar upper surface, an elongated fin on the planar upper surface of the substrate (wherein the length and the height of the fin are greater that the width of the fin) and an elongated gate conductor on the planar upper surface of the substrate. The length and the height of the gate conductor are greater than the width of the gate conductor. The fin comprises a center section comprising a semiconducting channel region and end sections distal to the channel region. The end sections of the fin comprise conductive source and drain regions. The gate conductor covers the channel region of the fin. The sidewalls of the channel region comprise a different crystal orientation than the sidewalls of the source and drain regions.

### BACKGROUND OF THE INVENTION

1. Field of the Invention

The embodiments of the invention generally relate to fin-type field effect transistors (finFETs), and, more particularly, to finFET structures (and associated formation methods) that have channel regions with V-shaped sidewalls.

2. Description of the Related Art

FinFETs are promising structures for enabling device density scaling beyond 45 nm. As in the case of planar metal oxide semiconductor field effect transistors (MOSFETs), independently optimizing the carrier mobility of both N- and P-type devices can enhance overall circuit performance. Established techniques for independent N and P mobility enhancement in planar transistors include strain engineering and multiple crystal orientations. Due to the unique structure of finFETs, new techniques are needed for imparting such mobility enhancement benefits with these devices.

### BRIEF SUMMARY OF THE INVENTION

In view of the foregoing, an embodiment of the invention provides a fin-type field effect transistor (FINFET) structure comprising a substrate having a planar upper surface, an elongated fin on the planar upper surface of the substrate (wherein the length and the height of the fin are greater that the width of the fin) and an elongated gate conductor on the planar upper surface of the substrate. Similarly, the length and the height of the gate conductor are greater than the width of the gate conductor.

The fin comprises a center section comprising a semiconducting channel region and end sections distal to the channel region. The end sections of the fin comprise conductive source and drain regions. The gate conductor covers the channel region of the fin. The sidewalls of the channel region comprise a different crystal orientation than the sidewalls of the source and drain regions.

Embodiments herein also include a method of forming a finFET structure that patterns an elongated fin on a planar upper surface of a substrate in a manner such that the length and the height of the fin are greater that the width of the fin, and patterns a protective mask over the fin. The protective mask comprises an elongated opening approximately perpendicular to a centerline of the fin that exposes the channel region.

The method alters a crystal orientation of only the center section of the fin in a manner such that sidewalls of the channel region comprise a different crystal orientation than sidewalls of the source and drain regions. The method forms an elongated gate conductor within the elongated opening of the protective mask on the planar upper surface of the substrate in a manner such that the length and the height of the gate conductor are greater than the width of the gate conductor. Then the method removes the protective mask, and dopes the source and drain regions in a manner such that the source and drain regions comprise conductors.

These and other aspects of the embodiments of the invention will be better appreciated and understood when considered in conjunction with the following description and the accompanying drawings. It should be understood, however, that the following descriptions, while indicating embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE SEVERAL VIEWS OF THE DRAWING

The embodiments of the invention will be better understood from the following detailed description with reference to the drawings, in which:

FIG. 1 is a perspective view schematic diagram of a finFET structure according to embodiments herein;

FIG. 2 is a perspective view schematic diagram of a finFET structure according to embodiments herein;

FIG. 3 is a perspective view schematic diagram of a finFET structure according to embodiments herein;

FIG. 4 is a perspective view schematic diagram of a finFET structure according to embodiments herein;

FIG. 5 is a perspective view schematic diagram of a finFET structure according to embodiments herein;

FIG. 6 is a perspective view schematic diagram of a finFET structure according to embodiments herein;

FIG. 7 is a perspective view schematic diagram of a finFET structure according to embodiments herein;

FIG. 8 is a perspective view schematic diagram of a finFET structure according to embodiments herein;

FIG. 9 is a top view schematic diagram of a finFET structure according to embodiments herein;

FIG. 10 is a perspective view schematic diagram of a finFET structure according to embodiments herein;

FIG. 11 is a top view schematic diagram of a finFET structure according to embodiments herein;

FIG. 12 is a top view schematic diagram of a finFET structure according to embodiments herein;

FIG. 13 is a perspective view schematic diagram of a finFET structure according to embodiments herein;

FIG. 14 is a top view schematic diagram of a N- and P-type finFET structures on a single substrate according to embodiments herein;

FIG. 15 is a chart illustrating etching properties of different crystal orientations; and

FIG. 16 is a perspective view schematic diagram of different crystal orientations.

### DETAILED DESCRIPTION OF THE INVENTION

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

This disclosure presents a method of making and a final structure for finFETs with different channel orientations on a single silicon substrate. One embodiment independently optimizes N- and P-type devices by starting with (100) silicon-on-insulator (SOI) wafers and deposits or grows faceted epitaxial material only on the PFET channel regions selective to the (111) surface. This puts the N- and P-channels on different crystal planes that optimize their respective carrier mobility's. The resulting (111) PFET channel is self-aligned to the gate conductor to allow maximum packing density. Another embodiment etches the channel regions of the P-type finFETs to also form channel sidewalls with the (111) crystal orientation, without changing the crystal orientation from (100) for the N-type finFET channel regions.

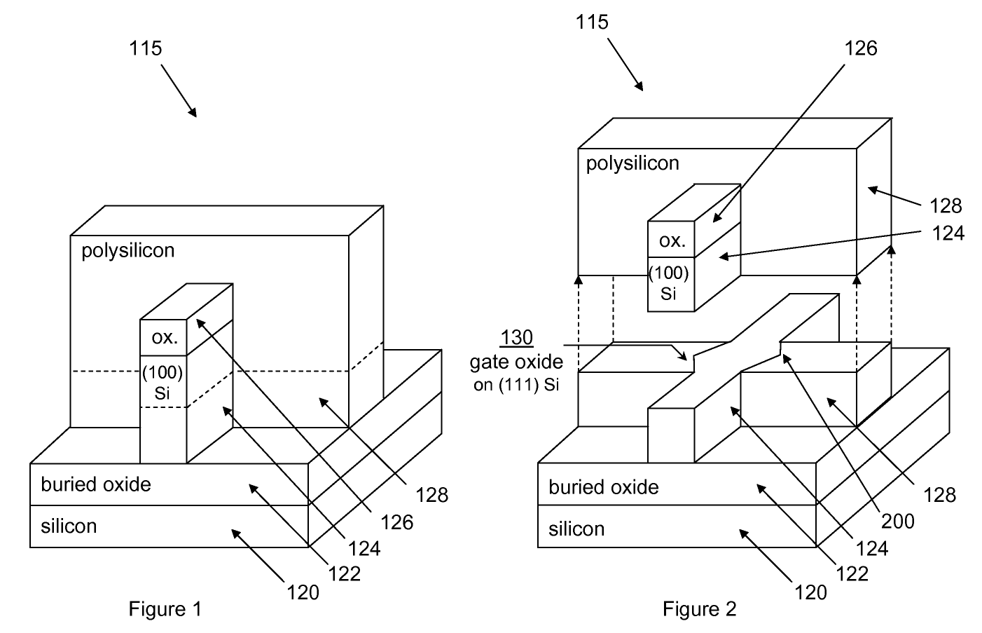

More specifically, as shown in FIGS. 1 and 2, one embodiment of the invention provides a fin-type field effect transistor (finFET) structure 115. FIGS. 1 and 2 illustrate the same structure; however, the top half of the structure is separated from the bottom half of the structure in FIG. 2, as shown by the arrows, in order to illustrate the shape of the channel region.

This structure 115 comprises a substrate 120, 122 having a planar upper surface. The substrate is part of a SOI structure and therefore includes a silicon layer 120 and an insulator layer 122 (buried oxide). Methodologies, materials, processes, etc. for utilizing SOI substrates within the formation of finFET devices are well-known to those ordinarily skilled in the art as evidenced by the disclosures within U.S. Pat. Nos. 7,352,034; 7,348,641; 7,348,225; 7,323,374; and 7,315,994 (the complete disclosures of which are incorporated herein by reference) and, in order to focus the reader on the salient aspects of the invention, the details regarding the use of such substrates, and the formation of finFET devices is omitted herefrom.

An elongated fin 124 is positioned on the planar upper surface of the substrate 120, 122 (wherein the length and the height of the fin 124 are greater that the width of the fin 124) and an elongated gate conductor 128 is positioned on the planar upper surface of the substrate 120, 122. Similarly, the length and the height of the gate conductor 128 are greater than the width of the gate conductor 128. The gate conductor 128 is insulated from the fin 124 by a gate insulator 130 (e.g., gate oxide). In the examples disclosed herein, the centerline of the gate conductor 128 is approximately perpendicular to the centerline the fin 124, although the gate conductor 128 could intersect the fin 124 at angles other than 90°, such as 60°, 45°, 30°, etc.

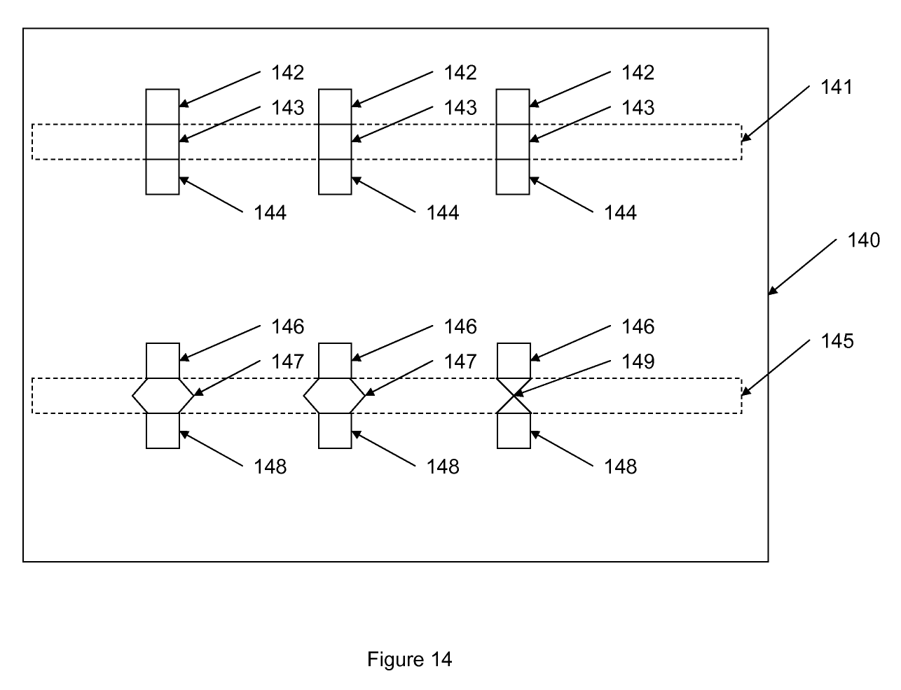

The fin 124 comprises a center section comprising a semiconducting channel region and end sections distal to the channel region. The end sections of the fin 124 comprise conductive source and drain regions. The gate conductor 128 covers the channel region of the fin 124. As discussed in greater detail below, the channel sections 143, 147, 149, the source and drain regions 142, 144, 146, 148 of various N-type and P-type finFETs are individually illustrated in FIG. 14.

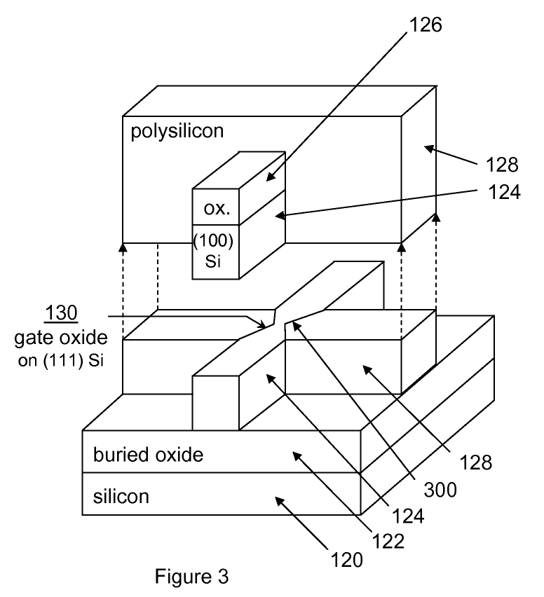

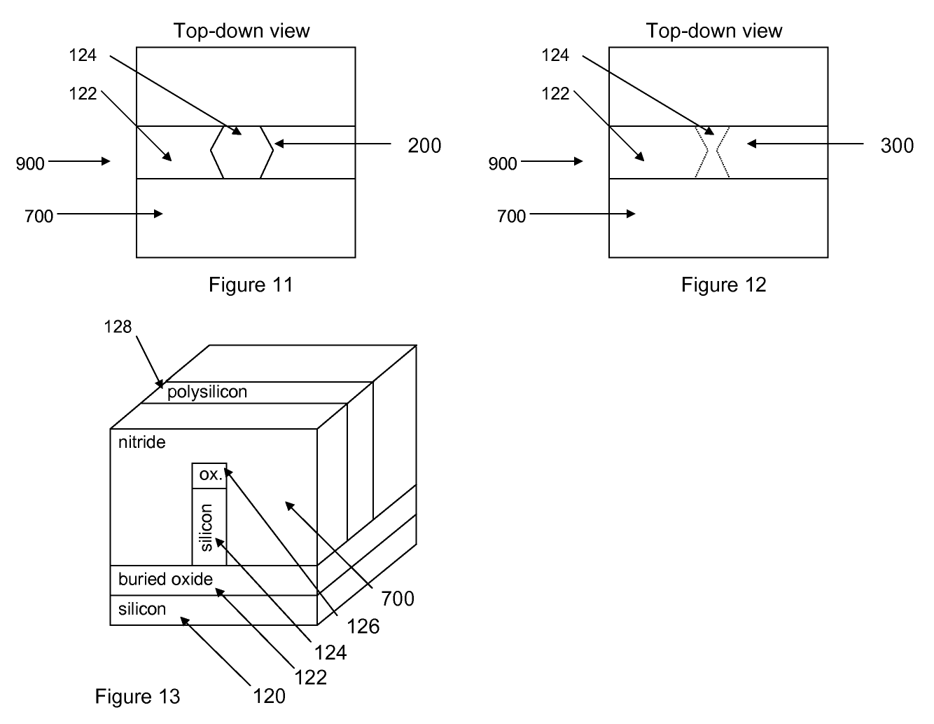

One feature of embodiments herein is that (as illustrated in FIGS. 2 and 3) the sidewalls 200, 300 of the channel region comprise a different crystal orientation than the sidewalls of the source and drain regions. When viewed from the top, the sidewalls of the channel regions form V-shaped structures, as shown in FIGS. 11 and 12.

For example, the sidewalls of the channel region can have a 111 crystal orientation, and the sidewalls of the source and drain regions have a 100 crystal orientation. While two specific crystal orientations are used in this example, the embodiments herein are not limited to these specific orientations, and instead any crystal orientations can be utilized so long as the different types (N-type, P-type) of transistors utilize channel regions with different crystal orientations. For example, FIG. 16 illustrates three common crystal orientations (100, 110, 111) using graphs 160, 162, and 164.

Thus, as shown in FIGS. 2, 3, 11 and 12, the sidewalls of the channel regions can comprise V-shaped protrusions 200 extending outwardly from the fin relative to sidewalls of the source and drain regions. Such protrusions 200 comprise faceted epitaxial material formed on the sidewalls of the channel region. Alternatively, the sidewalls of the channel region comprise V-shaped recesses 300 extending inwardly from the fin relative to sidewalls of the source and drain regions.

This allows different types of transistors to be differently tuned to operate most effectively. Thus, the fin 124 and the gate conductor 128 can comprise a first type (e.g., positive type or “P-type”) of transistor and the structure can further include at least one second type of similar finFET transistor that is also formed on the substrate 120, 122. This second type of transistor has an opposite doping polarity (e.g., negative type or “N-type”) relative to the first type of transistor. With embodiments herein, the sidewalls of channel regions of the second type of transistor do not have the V-shaped protrusions 200 or recesses 300, but instead are planar with the remainder of the fin 124. In other words, as shown in FIG. 14 the sidewalls of the channel regions 143 of the N-type transistors are coplanar with and have the same crystal orientation as sidewalls of source and drain regions 142, 144 of the N-type of transistor.

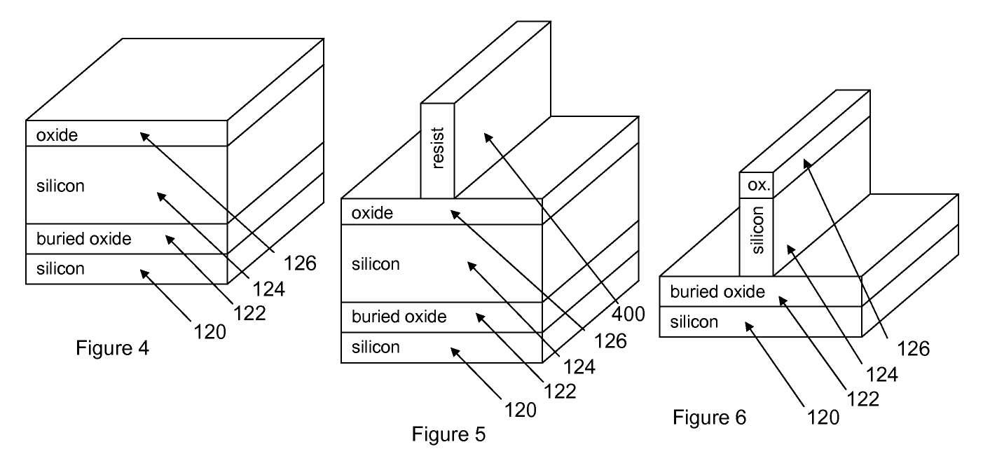

As shown in FIGS. 4-15 embodiments herein also include a method of forming the finFET structure 115 that is discussed above. Using processes and materials that are discussed in greater detail in the previously mentioned U.S. patents, the method begins with an SOI structure comprising a silicon layer 120, a buried oxide layer 122, a (100) crystal orientation silicon layer 124, and an oxide layer 126 as shown in FIG. 4. Using a patterned mask 400 (e.g., photoresist formed by the conventional processes including deposition, exposure, development, and selective removal in FIG. 5), the method uses any conventionally known material removal process (e.g., selective etching) to pattern the elongated fin 124 of single crystal silicon having a (100) crystal orientation on the planar upper surface of the insulator substrate 122 in such a manner such that the length and the height of the fin 124 are greater that the width of the fin 124, to produce the structure shown in FIG. 6.

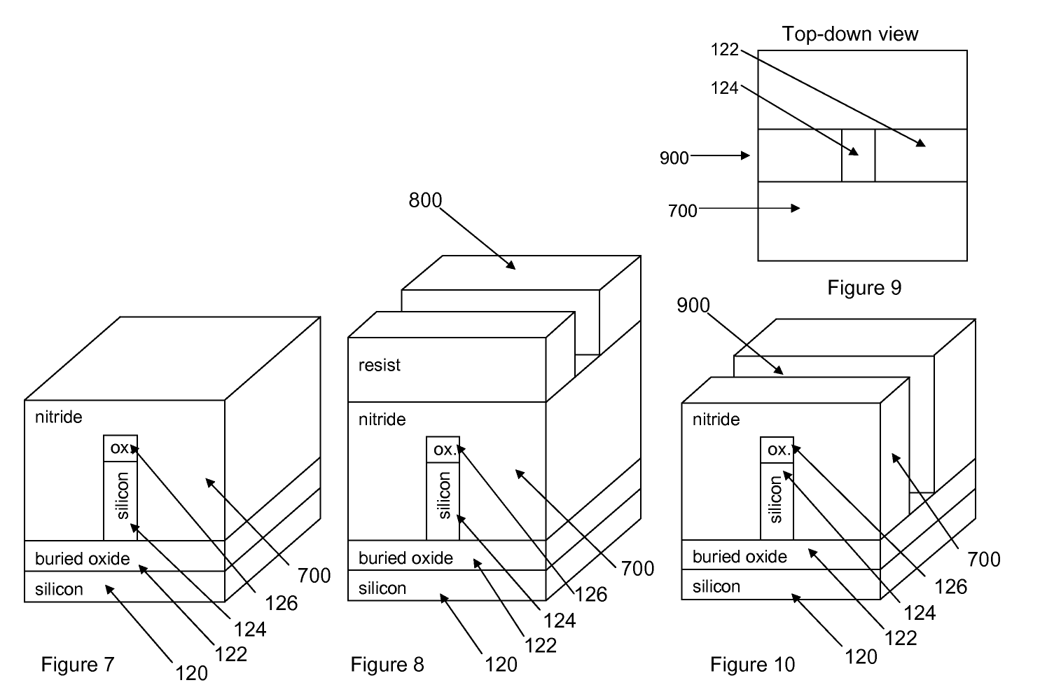

As shown in FIG. 7, the method then deposits a material 700 capable of being selectively removed (nitride). Another mask 800 (e.g., a photoresist similar to item 400) shown in FIG. 8 is then patterned and another selective material removal process is used to pattern the material 700 as shown in FIGS. 9 and 10 to patterns a protective mask 700 over the fin 124. As shown most clearly in the top view in FIG. 9, the protective mask 700 comprises an elongated opening 900 approximately perpendicular to a centerline of the fin 124 that exposes the channel region of the fin 124.

With the channel region of the fin 124 exposed, the method can then alter the crystal orientation of only the center section (channel region 147, 149) of the fin 124 using any of a number of conventional processes in a manner such that sidewalls of the channel region 147, 149 comprise a different crystal orientation than sidewalls of the source and drain regions.

More specifically, the altering of the crystal orientation can be performed in a manner such that sidewalls of the channel region comprise V-shaped protrusions 200 extending outwardly relative to sidewalls of the source and drain regions, as shown in FIG. 11. For example, the V-shaped protrusions 200 can be formed by any material appropriate formation process, including epitaxially growing facets on the sidewalls of the channel region.

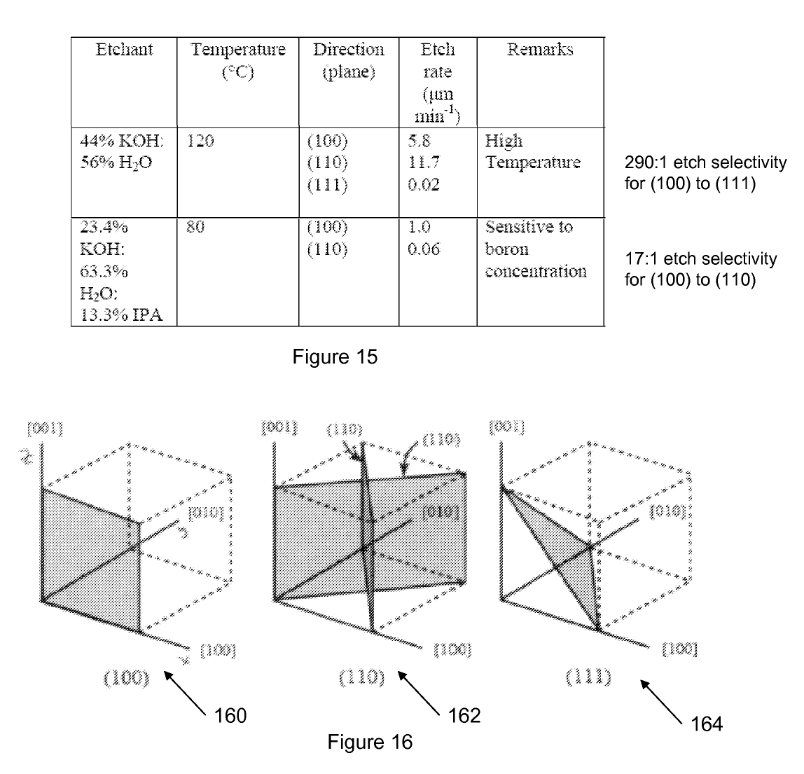

Alternatively, the altering of the crystal orientation can be performed in a manner such that the sidewalls of the channel region comprise V-shaped recesses 300 extending inwardly relative to sidewalls of the source and drain regions. The altering of the crystal orientation comprises any controllable material removal process, such as crystalographic etching the channel region (for example, using ammonium hydroxide or other hydroxide solutions). For example, as shown in FIG. 15, many different types of combinations of etchants, temperatures, directions, and etch rates can be utilized to form whenever crystal orientation is desired for a specific application.

The method forms an elongated gate conductor 128 (that can comprise any conductive material, such as metals, alloys, polysilicon, etc.) within the elongated opening 900 of the protective mask 700 on the planar upper surface of the substrate 124 in any conventional manner (sputtering, deposition, damascene processing, etc.) such that the length and the height of the gate conductor 128 are greater than the width of the gate conductor 128. Then, the method removes the protective mask 800 using any appropriate selective material removal process to produce of the structures shown in FIGS. 1 and 2. After the distal ends of the fin 124 are exposed, they can be implanted with impurities (doped) in any conventionally known manner such that the source and drain regions comprise conductors.

The fin 124 and the gate conductor 128 together comprise a first type (e.g., P-type) of transistor and the method can further comprise simultaneously forming a second opposite type of transistor on the substrate. Again, this second type of transistor has an opposite doping polarity (e.g., N-type) relative to the first type of transistor and the sidewalls of channel regions of the second type of transistor have the same crystal orientation as sidewalls of source and drain regions of the second type of transistor. A schematic diagram illustrating N-type and P-type finFETs on a single substrate 140 are shown in FIG. 14.

More specifically, the N-type finFETs are referenced generally by items 141-144 and the P-type finFETs a reference generally by items 145-149 in FIG. 14. The gate conductors are generally shown as items 141 and 145, and are shown as being transparent in FIG. 14. As shown in FIG. 14, the sidewalls of the channel regions 143 of the fins of the N-type finFETs are coplanar with the sidewalls of the source and drain regions 142, 144. To the contrary, the channel regions 147, 149 of the P-type finFETs have sidewalls that are not coplanar with the sidewalls of the source and drain regions 146, 148. Note that both the protrusions 200 and recesses 300 are shown in the single structure in FIG. 14; however, one ordinarily skilled in the art would understand that this is for illustration purposes only and that the P-type finFETs of a specific structure will generally only include either protrusions or recesses and (at least within the same localized region of a given chip) generally will not include both protrusion type and recessed type finFETs.

Further, the different types of transistors shown in FIG. 14 can be simultaneously formed by only forming the openings 900 in the protective mask 700 above the P-type finFETs and not forming openings above the N-type finFETs. This allows the processing applied to the channel regions of the P-type finFETS to not affect the channel regions of the N-type finFETs. However, additional openings that are similar to openings 900 can be formed subsequent to the protrusion 200 or recess 300 formation above the N-type finFETs to allow the gate conductors 141, 145 to be simultaneously formed for both types of transistors. Alternatively, the gate conductors 141 for the N-type finFETs can be formed in a separate process.

The previous examples describe altering the channel regions of the P-type finFETs and not altering the channel regions of the N-type finFETs; however, one ordinarily skilled in the art will readily understand that the processing can be completely reversed. For example, silicon fins can be formed from a material having a (111) crystal orientation (suitable for P-type finFETs) and the channel regions of the N-type finFETs could be altered to include recesses and/or protrusions that create a (100) crystal orientation. Therefore, one ordinarily skilled in the art would understand from the foregoing that the embodiments herein also include methods and structures where the P-type finFET channel regions are not altered and are coplanar with their respective source and drain regions and the N-type finFET channel regions are altered to include protrusions or recesses.

With the structures and methods discussed above, complementary finFET transistors that utilize channel regions having different crystal orientations can be formed simultaneously on a single substrate to allow both types of transistors to operate in the most effective manner. With such processing and structures, the reliability, yield, and speed of integrated circuits is dramatically improved while the cost of such structures is decreased.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of preferred embodiments, those skilled in the art will recognize that the embodiments of the invention can be practiced with modification within the spirit and scope of the appended claims.

1. A structure comprising:
a substrate having a planar upper surface;
an elongated fin on said planar upper surface of said substrate, wherein the length and the height of said fin are greater that the width of said fin, and
an elongated gate conductor on said planar upper surface of said substrate,
wherein the length and the height of said gate conductor are greater than the width of said gate conductor,
wherein said fin comprises a center section comprising a semiconducting channel region and end sections distal to said channel region,
wherein said end sections of said fin comprise conductive source and drain regions,
wherein said gate conductor covers said channel region of said fin, and
wherein sidewalls of said channel region comprise a different crystal orientation than sidewalls of said source and drain regions.

2. The structure according to claim 1, wherein said sidewalls of said channel region comprise V-shaped protrusions extending outwardly relative to sidewalls of said source and drain regions.

3. The structure according to claim 2, wherein said protrusions comprise faceted epitaxial material formed on said sidewalls of said channel region.

4. The structure according to claim 1, wherein said sidewalls of said channel region comprise V-shaped recesses extending inwardly relative to sidewalls of said source and drain regions.

5. The structure according to claim 1, wherein said fin and said gate conductor comprise a first type of transistor,
wherein said structure further comprises a second type of transistor formed on said substrate,
wherein said second type of transistor has an opposite doping polarity relative to said first type of transistor, and
wherein sidewalls of channel regions of said second type of transistor have the same crystal orientation as sidewalls of source and drain regions of said second type of transistor.

6. The structure according to claim 5, wherein said first type of transistor comprises a P-type transistor and said second type of transistor comprises an N-type transistor.

7. The structure according to claim 1, wherein a centerline of said gate conductor is approximately perpendicular to a centerline said fin.

8. A structure comprising:
a substrate having a planar upper surface;
an elongated fin on said planar upper surface of said substrate, wherein the length and the height of said fin are greater that the width of said fin, and
an elongated gate conductor on said planar upper surface of said substrate,
wherein the length and the height of said gate conductor are greater than the width of said gate conductor,
wherein said fin comprises a center section comprising a semiconducting channel region and end sections distal to said channel region,
wherein said end sections of said fin comprise conductive source and drain regions,
wherein said gate conductor covers said channel region of said fin,
wherein sidewalls of said channel region have a 111 crystal orientation, and
wherein sidewalls of said source and drain regions have a 100 crystal orientation.

9. The structure according to claim 8, wherein said sidewalls of said channel region comprise V-shaped protrusions extending outwardly relative to sidewalls of said source and drain regions.

10. The structure according to claim 9, wherein said protrusions comprise faceted epitaxial material formed on said sidewalls of said channel region.

11. The structure according to claim 8, wherein said sidewalls of said channel region comprise V-shaped recesses extending inwardly relative to sidewalls of said source and drain regions.

12. The structure according to claim 8, wherein said fin and said gate conductor comprise a first type of transistor,
wherein said structure further comprises a second type of transistor formed on said substrate,
wherein said second type of transistor has an opposite doping polarity relative to said first type of transistor, and
wherein sidewalls of channel regions of said second type of transistor have the same crystal orientation as sidewalls of source and drain regions of said second type of transistor.

13. The structure according to claim 12, wherein said first type of transistor comprises a P-type transistor and said second type of transistor comprises an N-type transistor.

14. The structure according to claim 8, wherein a centerline of said gate conductor is approximately perpendicular to a centerline said fin.

15-20. (canceled)

21. A structure comprising:
a substrate having a planar upper surface;
an elongated fin on said planar upper surface of said substrate, wherein the length and the height of said fin are greater that the width of said fin; and
an elongated gate conductor on said planar upper surface of said substrate, wherein the length and the height of said gate conductor are greater than the width of said gate conductor,
wherein said fin comprises a center section comprising a semiconducting channel region and end sections distal to said channel region,
wherein said end sections of said fin comprise conductive source and drain regions,
wherein said gate conductor covers said channel region of said fin, and
wherein sidewalls of said channel region comprise a different crystal orientation than sidewalls of said source and drain regions and V-shaped recesses extending inwardly relative to sidewalls of said source and drain regions.

22. The structure according to claim 21, wherein said protrusions comprise faceted epitaxial material formed on said sidewalls of said channel region.

23. The structure according to claim 21, wherein said fin and said gate conductor comprise a first type of transistor,
wherein said structure further comprises a second type of transistor formed on said substrate,
wherein said second type of transistor has an opposite doping polarity relative to said first type of transistor, and
wherein sidewalls of channel regions of said second type of transistor have the same crystal orientation as sidewalls of source and drain regions of said second type of transistor.

24. The structure according to claim 23, wherein said first type of transistor comprises a P-type transistor and said second type of transistor comprises an N-type transistor.

25. The structure according to claim 21, wherein a centerline of said gate conductor is approximately perpendicular to a centerline said fin.
